(19) United States
(12) Patent Application Publication
(10) Pub. No.: US 2017/0271567 A1
(43) Pub. Date: Sep. 21, 2017

(54) COPPER ALLOY PLATE STRIP FOR USE IN LED LEAD FRAME

(71) Applicant: KABUSHIKI KAISHA KOBE SEIKO SHO (KOBE STEEL, LTD.), Kobe-shi, Hyogo (JP)

(72) Inventors: Masayasu NISHIMURA, Yamaguchi (JP); Yasushi MASAGO, Yamaguchi (JP); Akira FUGONO, Yamaguchi (JP)

(73) Assignee: KABUSHIKI KAISHA KOBE SEIKO SHO (KOBE STEEL, LTD.), Kobe-shi, Hyogo (JP)

(21) Appl. No.: 15/505,476

(22) PCT Filed: Aug. 17, 2015
(86) PCT No.: PCT/JP2015/073036

§ 371 Date: Feb. 21, 2017

(30) Foreign Application Priority Data
Aug. 22, 2014 (JP) 2014-169481

(51) Int. Cl. H01L 33/62; C22F 1/08; C25D 3/38; C25D 3/46; H01B 5/02; C25D 5/10; C25F 1/00; C23G 1/10; B32B 15/01; H01B 1/02; C22C 9/04; C25D 5/34

(52) U.S. Cl. CPC H01L 33/62; C22C 9/04; C22F 1/08; C25D 3/38; C25D 3/46; C25D 5/34; C25D 5/10; C25F 1/00; C23G 1/103; B32B 15/018; H01B 1/026; H01B 5/02

(57) ABSTRACT

A copper alloy sheet or strip for a lead frame of LED includes specific amounts of Fe, P, Zn, and Sn with the remainder being Cu and unavoidable impurities. A surface roughness thereof is less than 0.06 μm in terms of arithmetic average roughness Ra and is less than 0.5 μm in terms of ten-point average roughness Rz_{JIS}. The number of groove-shaped recesses present on the surface, each having a length of 5 μm or more and a depth of 0.25 μm or more, is 2 or less in a range of a square of 200 μm×200 μm with a pair of its sides running in transverse to a rolling direction. A thickness of a work affected layer formed of fine grains on the surface is 0.5 μm or less.

### TECHNICAL FIELD

The present invention relates to a copper alloy sheet or strip (sheet and strip) to be used, for example, as a lead frame of LED, and an Ag-plated copper alloy sheet or strip.

### BACKGROUND ART

Recently, a light-emitting device using a Light Emitting Diode (LED) as a light source is widespread in a broad range of fields because of its advantages of energy saving and long life. An LED element is fixed to a copper alloy lead frame excellent in thermal conductivity and electrical conductivity and incorporated into a package. In order to efficiently extract light emitted from the LED element, an Ag plating coat is formed as a reflective film on a surface of the copper alloy lead frame. The LED package is used as a backlight of illuminations, personal computers, mobile phones, etc., and the illumination must be therefore brighter, leading to a more and more growing demand to increase the brightness of an LED package.

For increasing the brightness of an LED package, there are a method of increasing the brightness of the LED element itself and a method of enhancing the quality (increasing the reflectance) of Ag plating. However, the brightness of an LED element has been enhanced almost to the limit, and only a slight increase of brightness results in a significant rise of the element cost. Accordingly, the demand for increased reflectance of the Ag plating is becoming strong in recent years. As a copper alloy for a lead frame, to which Ag plating is applied, a polish-finished product having an arithmetic average roughness Ra of about 0.08 μm or a roll-finished product having an arithmetic average roughness Ra of about 0.06 μm is conventionally used, but the reflectance after Ag plating is about 91% at most, and a higher reflectance is demanded.

On the other hand, a high-brightness LED used mainly for illuminations unexpectedly generates a large amount of heat and since this heat may deteriorate the LED element itself or a resin therearound and impair a long life that is a characteristic feature of LED, importance is placed on measures for heat dissipation of the LED element. As the copper alloy for a lead frame of LED, C194 having a strength of 450 MPa and an electrical conductivity of about 70% IACS is often used (see, Patent Documents 1 and 2). However, as one of the measures for heat dissipation, a copper alloy for a lead frame with a higher electrical conductivity (thermal conductivity) than that of C194 is demanded.

### PRIOR ART LITERATURE

### Patent Documents

Patent Document 1: JP-A-2011-252215

Patent Document 2: JP-A-2012-89638 (paragraph 0058)

### SUMMARY OF THE INVENTION

### Problems that the Invention is to Solve

An object of the present invention is, in pursuance of measures for heat dissipation of an LED package, to use a Cu—Fe—P copper alloy having a higher electrical conductivity than that of C194 as a material of the lead frame, improve the reflectance of an Ag plating reflective film formed on a surface of the alloy, and increase the brightness of an LED package.

### Means for Solving the Problems

In order to improve the reflectance of an Ag plating reflective film, it is conceivable to reduce the surface roughness of a copper alloy sheet or strip as a lead frame material, but the reflectance of an Ag plating reflective film is not improved only by this technique. On the basis of the knowledge of the present inventors, a fine defect such as an oil pit or a streaky pattern is formed in the process of cold rolling on the surface of the copper alloy sheet or strip, or a work affected layer is formed by polishing finish, and such a defect or layer exercises an effect on the surface roughness, grain size, etc. of the Ag plating reflective film and prevents improvement of the reflectance of the Ag plating reflective film. The present invention has been accomplished based on this knowledge.

The copper alloy sheet or strip (sheet and strip) for a lead frame of LED according to the present invention contains Fe: from 0.01 to 0.5 mass %, P: from 0.01 to 0.20 mass %, Zn: from 0.01 to 1.0 mass %, and Sn: from 0.01 to 0.15 mass %, with the remainder consisting of Cu and unavoidable impurities, and if desired, further contains one member or two or more members of Co, Al, Cr, Mg, Mn, Ca, Pb, Ni, Ti, Zr, Si and Ag in a total amount of 0.02 to 0.3 mass %. In this copper alloy sheet or strip, a surface roughness is less than 0.06 μm in terms of arithmetic average roughness Ra and is less than 0.5 μm in terms of ten-point average roughness Rz_{JIS}, the number of groove-shaped recesses present on the surface, each having a length of 5 μm or more and a depth of 0.25 μm or more, is 2 or less (inclusive of 0) in an area of a square of 200 μm×200 μm, and a thickness of a work affected layer composed of fine grains on the surface is 0.5 μm or less.

### Advantageous Effects of the Invention

The copper alloy sheet or strip according to the present invention has a tensile strength of 450 MPa or more, an electrical conductivity of 80% IACS or more, and a hardness reduction of less than 10% after heating of 400° C.×5 minutes, and thus, the copper alloy sheet or strip satisfies all of strength, electrical conductivity and softening resistance, which are required of a lead frame of LED. In addition, according to the present invention, the lead frame having a high electrical conductivity (thermal conductivity) serves as a heat dissipation path, and the heat dissipation of an LED package can thereby be enhanced.

Furthermore, in the copper alloy sheet or strip according to the present invention, the surface roughness of an Ag plating reflective film formed on the surface can be 0.3 μm or less in terms of ten-point average roughness Rz_{JIS} and consequently, the reflectance of the Ag plating reflective film can be improved to 92% or more, so that high brightness of an LED package can be realized.

### BRIEF DESCRIPTION OF THE DRAWINGS

FIG. 1 A scanning electron micrograph illustrating the surface morphology (particularly, recesses) of the copper alloy sheet or strip according to Comparative Example (Test No. 11) of the present invention.

### MODE FOR CARRYING OUT THE INVENTION

The present invention is described below more specifically.

### (Chemical Composition of Copper Alloy)

The copper alloy according to the present invention contains Fe: from 0.01 to 0.5 mass %, P: from 0.01 to 0.20 mass %, Zn: from 0.01 to 1.0 mass %, and Sn: from 0.01 to 0.15 mass %, with the remainder consisting of Cu and unavoidable impurities, and if desired, contains one member or two or more members of Co, Al, Cr, Mg, Mn, Ca, Pb, Ni, Ti, Zr, Si and Ag in a total amount of 0.02 to 0.3 mass %.

In the copper alloy above, Fe forms a compound with P and the compound plays a role in enhancing strength and electrical conductivity properties. However, if the Fe content exceeds 0.5 mass %, the reduction in the electrical conductivity and thermal conductivity of the copper alloy is caused, and if the content is less than 0.01 mass %, the strength as a lead frame for LED cannot be obtained. If the P content exceeds 0.2 mass %, the electrical conductivity and thermal conductivity of the copper alloy are deteriorated, and if the content is less than 0.01 mass %, the strength required of a lead frame for LED cannot be obtained. For these reasons, the Fe content is from 0.01 to 0.5 mass %, and the P content is from 0.01 to 0.20 mass %. The ratio [Fe/P] between the Fe content and the P content is preferably from 2 to 5 in view of strength and electrical conductivity.

The lower limit of the Fe content is preferably 0.03 mass %, more preferably 0.05 mass %, and the upper limit of the Fe content is preferably 0.45 mass %, more preferably 0.40 mass %. On the other hand, the lower limit of the P content is preferably 0.015 mass %, more preferably 0.020 mass %, and the upper limit of the P content is preferably 0.17 mass %, more preferably 0.15 mass %.

Zn has a function of enhancing the thermal separation resistance of solder and plays a role in maintaining solder joint reliability when an LED package is fixed to a base. However, if the Zn content is less than 0.01 mass %, this is insufficient to satisfy the thermal separation resistance of solder, and if the content exceeds 1.0 mass %, the electrical conductivity and thermal conductivity of the copper alloy are deteriorated. Accordingly, the Zn content is from 0.01 to 1.0 mass %.

Sn contributes to enhancement of the strength of the copper alloy, but if the Sn content is less than 0.01 mass %, sufficient strength is not obtained. If the Sn content exceeds 0.20 mass %, the electrical conductivity and thermal conductivity of the copper alloy are deteriorated. Accordingly, the Sn content is from 0.01 to 0.20 mass %.

The lower limit of the Zn content is preferably 0.03 mass %, more preferably 0.05 mass %, and the upper limit of the Zn content is preferably 0.80 mass %, more preferably 0.60 mass %.

On the other hand, the lower limit of the Sn content is preferably 0.02 mass %, more preferably 0.04 mass %, and the upper limit of the Sn content is preferably 0.17 mass %, more preferably 0.15 mass %.

Co, Al, Cr, Mg, Mn, Ca, Pb, Ni, Ti, Zr, Si and Ag, which are added as a subsidiary component(s) according to need, have an effect of enhancing the strength and softening resistance of the copper alloy. In order to obtain the effect above by adding these subsidiary components to the copper alloy, they are preferably incorporated in a total amount of 0.02 mass % or more. However, if these subsidiary components are incorporated in a total amount of more than 0.3 mass %, the thermal conductivity and electrical conductivity are deteriorated. Accordingly, in the case of adding these subsidiary components, the total content thereof is from 0.02 to 0.3 mass %. Here, Pb reduces the hot rolling property, and the content thereof is therefore preferably 0.01 mass % or less.

The total content of subsidiary components is preferably 0.03 mass % or more and preferably 0.2 mass % or less.

### (Surface Configuration of Copper Alloy Sheet or Strip)

The reflection properties of the Ag plating reflective film are affected by the surface configuration of the copper alloy sheet or strip as a material for plating, specifically, the surface roughness and the number of recesses present on the surface, and the thickness of a work affected layer formed on the surface.

The surface roughness of the copper alloy sheet or strip is, in a direction where the largest surface roughness is developed (usually transverse to a rolling direction), less than 0.06 μm in terms of arithmetic average roughness Ra and is less than 0.5 μm in terms of ten-point average roughness Rz_{JIS}. The arithmetic average roughness Ra and the ten-point average roughness Rz_{JIS} are specified in JIS B 0601:2001. If the arithmetic average roughness Ra is 0.06 μm or more or the ten-point average roughness Rz_{JIS} exceeds 0.5 μm, the surface roughness of the Ag plating reflective film is increased, and the reflectance of the Ag plating reflective film cannot be 92% or more.

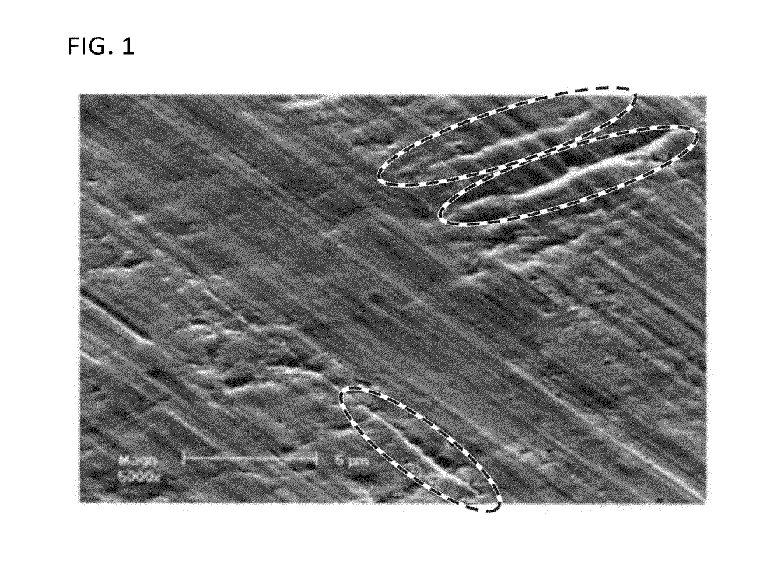

The recess present on the surface is a groove-shaped recess having a length of 5 μm or more and a depth of 0.25 μm or more, and the number of recesses is 2 or less (inclusive of 0) in the range of an arbitrarily selected square of 200 μm×200 μm (with a pair of its sides running in transverse to the rolling direction). The recess above is formed in transverse to a rolling direction or in parallel to a rolling direction. The recess and the vicinity thereof have large unevenness compared with other portions, and partial unevenness is therefore likely to be generated in the Ag plating reflective film. If the number of recesses in the region of the square above exceeds 2, a dent, etc. is readily produced in the Ag plating reflective film, and the reflectance of the Ag plating reflective film cannot be 92% or more. FIG. 1 illustrates a scanning electron micrograph of the surface of the copper alloy sheet or strip containing recesses. In FIG. 1, with respect to a groove-shaped recess having a width of more than 5 μm, two recesses (portions surrounded by the dashed line) are formed substantially in transverse to the rolling direction, and one recess (a portion surrounded by the dashed line) is formed substantially in parallel to the rolling direction.

On the surface of the cold-rolled copper alloy sheet or strip, (1) an amorphous Beilby layer, (2) a fiber•refinement layer (fine grain layer), and (3) an elastically strained layer are formed in this order from the surface. In general, these three layers are collectively called a work affected layer. On the other hand, in the present invention, among others, (1) and (2) above are collectively referred to as “a work affected layer composed of fine grains”. The layers of (1) and (2), the layer of (3) and a base material are clearly different in the grain microstructure and can therefore be easily distinguished. The work affected layer exercises an effect on the texture of the Ag plating reflective film and if the total thickness of the work affected layer (the layers (1) and (2)) composed of fine grains exceeds 0.5 μm, the surface roughness of the Ag plating reflective film is increased, and the reflectance of the Ag plating reflective film cannot be 92% or more. Accordingly, the thickness of the work affected layer composed of fine grains is 0.5 μM or less. Here, in a copper alloy sheet or strip that is polished after finish cold rolling, the thickness of the work affected layer composed of fine grains exceeds 0.5 μm in many cases.

### (Ag Plating Reflective Film)

The surface configuration of the Ag plating reflective film is greatly affected by the surface configuration of the copper alloy sheet or strip as a material. When the surface configuration (the surface roughness, the number of recesses present on the surface, the thickness of the work affected layer formed on the surface) of the copper alloy sheet or strip is in the ranges above, the surface roughness of the Ag plating reflective film can be 0.3 μM or less in terms of ten-point average roughness Rz_{JIS}. The reflectance of the Ag plating reflective film is said to be affected by the grain size and crystalline orientation of the Ag plating reflective film. When the surface roughness of the Ag plating reflective film is 0.3 μm or less in terms of ten-point average roughness Rz_{JIS}, the Ag plating reflective film can have a grain size of 13 μm or more and a crystalline orientation ((001) crystallographic orientation) of 0.4 or more, so that the reflectance of the Ag plating reflective film can be increased to 92% or more. On the other hand, if the ten-point average roughness Rz_{JIS} of the Ag plating reflective film exceeds 0.3 μm, the Ag plating reflective film cannot have a grain size of 13 μm or more and a crystalline orientation ((001) crystallographic orientation) of 0.4 or more or cannot satisfy either one of the above-described grain size and crystalline orientation, and as a result, the reflectance of the Ag plating reflective film cannot be increased to 92% or more.

### (Production Method of Copper Alloy Sheet or Strip)

The Cu—Fe—P copper alloy sheet or strip is usually produced by subjecting an ingot to scalping, hot rolling, and rapid cooling or solution treatment after hot rolling, and then cold rolling, precipitation annealing, and finish cold rolling. The cold rolling and precipitation annealing are repeated as needed, and low-temperature annealing is performed as needed after the finish cold rolling. In the case of the copper alloy sheet or strip according to the present invention as well, this production process need not be greatly changed. Appropriate conditions for melting/casting and hot rolling are as follows, and precipitation of coarse Fe, Fe—P, Fe—P—O, etc. can thereby be prevented.

In the melting/casting, Fe is added to a molten copper alloy at 1,200° C. or more and melted, and the melt is cast while continuously keeping the molten alloy temperature at 1,200° C. or more. If a coarse Fe particle or an Fe inclusion particle (e.g., Cu—Fe—O, Fe—O) is present in the ingot, a recess on the surface of a product is likely to be generated. It is therefore effective not to allow entering of such a particle into the ingot by filtering the molten alloy during casting, in addition to preventing oxidation of iron by completely melting Fe added or controlling the melting atmosphere. Cooling of the ingot is performed at a cooling rate of 1° C./second or more both during solidification (in a solid-liquid coexistence state) and after solidification. For this purpose, in the case of continuous casting or semi-continuous casting, primary cooling in a mold and secondary cooling just beneath the mold must be made sufficiently effective. In the hot rolling, a homogenization treatment is performed at 900° C. or more, preferably at 950° C. or more, hot rolling is started at the temperature, the hot rolling end temperature is set to 650° C. or more, preferably 700° C. or more, and immediately after the completion of hot rolling, rapid cooling to 300° C. or less is performed using a large amount of water.

After precipitation annealing, in general, the material surface is mechanically polished so as to remove an oxide formed on the material surface. At this time, streaky unevenness (polishing mark) is introduced on the material surface and when final cold rolling is subsequently performed, the unevenness is likely to be crushed and remain as the above-described streaky pattern in the product (copper alloy sheet or strip). This streaky pattern may make it impossible to satisfy the requirements as to the surface roughness and the number of recesses in the copper alloy sheet or strip, and it is therefore preferable not to perform mechanical polishing after precipitation annealing. Mechanical polishing after precipitation annealing can be omitted by performing the precipitation annealing in a reducing atmosphere not to produce an oxide film on the material surface during annealing.

The surface roughness of the copper alloy sheet or strip is formed by transferring the surface profile of a rolling roll to the material surface in the finish cold rolling. The surface roughness (arithmetic average roughness Ra and ten-point average roughness Rz_{JIS}) of the copper alloy sheet or strip according to the present invention is very small, and the rolling roll for finish cold rolling must be therefore mirror-finished in response to the target surface roughness of the copper alloy sheet or strip. As the rolling roll, a high-speed steel roll composed of super-steel or a silicon nitride-based roll made of SiAlON, etc. is preferably used. Among others, a SiAlON roll has a Vickers hardness of about 1,600, and the surface morphology of the roll can be stably transferred to the material surface.

As the rolling conditions during finish cold rolling, the lubricant, the roll rotational speed, the rolling reduction, and the tensile tension (tension on the roll exit side) must be appropriately combined, and a copper alloy sheet or strip having desired surface profile (surface roughness, number of recesses, work affected layer) can be produced by performing the finish rolling under the following conditions.

As for the lubricant in finish cold rolling, it is preferable to use a paraffin-based lubricant having a transmittance of 90% or more for incident light at a wavelength of 550 nm and perform the rolling at a temperature of about 40° C. The transmittance as used herein means a relative transmittance of the lubricant above assuming that the transmittance of xylene for incident light at a wavelength of 550 nm is 100%. By using this lubricant, production of the above-described oil pit can be suppressed.

In the finish cold rolling, a total reduction of 20 to 70% of cold rolling by single-pass or multipass threading is performed using a roll having a roll diameter of approximately from 20 to 100 mm at a roll rotational speed of 200 to 700 mpm and a tensile tension (exit-side tension) of approximately from 50 to 200 N/mm². In the case of performing multipass threading in the finish cold rolling, it is preferred that the roughness of the rolls in the second and subsequent passes is finer than the roughness of the roll in the first pass and the rolling speed in the second and subsequent passes is lower than the rolling speed in the first pass. As the rotational speed of the roll is lower, as the tensile tension is smaller, and as the rolling reduction is larger, the transfer from the roll to the material surface is more successfully achieved, and as a result, not only a small stable surface roughness can be ensured for the copper alloy sheet or strip but also the number of recesses is decreased. However, if the rolling reduction is large, a work affected layer is readily formed. On the other hand, an opposite tendency to that is observed when the rotational speed of the roll is high, the tensile tension is large, and the rolling reduction is small. The reduction of the finish cold rolling may be determined depending on the desired mechanical property, but the reduction is preferably from 10 to 50% in the case of not performing low-temperature annealing such as stress relief annealing after the finish cold rolling, and the reduction is preferably from 30 to 90% in the case of performing stress relief annealing after rolling.

### Example 1

Copper alloys (Alloy Nos. 1 to 24) having the compositions shown in Tables 1 and 2 were melted under charcoal covering in atmospheric air in a small-sized electric melting furnace, and ingots having a thickness of 50 mm, a width of 80 mm, and a length of 180 mm were cast. The manufactured ingots were scalped on each of the front/rear surfaces by 5 mm, subjected to a homogenization treatment at 950° C., hot-rolled to sheet materials having a thickness of 12 mm t, and then rapidly cooled. Each of the front/rear surfaces of the sheet materials was scalped by about 1 mm. With respect to these sheet materials, after repeatedly performing cold rolling and precipitation annealing at 500 to 550° C. for 2 to 5 hours, finish cold rolling was performed at a reduction of 40% by using a mirror-finished SiAlON roll with a diameter of 50 mm to manufacture copper alloy strips having a thickness of 0.2 mm and a width of 180 mm, which were used as test materials. In the finish cold rolling, the above-described lubricant was used, and the roll rotational speed and the tensile tension were in the ranges above.

TABLE 1

| | | | | | | | Properties | | | |
|---|---|---|---|---|---|---|---|---|---|---|
| | | | | | | | | | | Softening |
| | | | | | | | | | Thermal | Resistance/ |
| | | | | | | | Tensile | Electrical | Separation | Hardness |
| Alloy | Chemical Component (mass %) | | | | | | Strength | Conductivity | Resistance of | Reduction |
| No. | Fe | P | Zn | Sn | Subsidiary Component | Cu | (MPa) | (% IACS) | Solder | Rate (%) |
| 1 | 0.3 | 0.1 | 0.3 | 0.03 | — | remainder | 468 | 87 | A | 1 |
| 2 | 0.4 | 0.1 | 0.3 | 0.03 | — | remainder | 473 | 85 | A | 1 |
| 3 | 0.08 | 0.03 | 0.3 | 0.03 | — | remainder | 452 | 90 | A | 6 |
| 4 | 0.3 | 0.15 | 0.3 | 0.03 | — | remainder | 473 | 82 | A | 1 |
| 5 | 0.1 | 0.02 | 0.3 | 0.03 | — | remainder | 455 | 89 | A | 6 |
| 6 | 0.3 | 0.1 | 0.8 | 0.03 | — | remainder | 471 | 85 | A | 1 |
| 7 | 0.3 | 0.1 | 0.02 | 0.03 | — | remainder | 468 | 88 | A | 2 |
| 8 | 0.3 | 0.1 | 0.3 | 0.13 | — | remainder | 473 | 85 | A | 1 |
| 9 | 0.3 | 0.1 | 0.3 | 0.01 | — | remainder | 467 | 88 | A | 2 |
| 10 | 0.3 | 0.1 | 0.3 | 0.03 | Co: 0.08, Al: 0.04, Cr: 0.08, | remainder | 471 | 81 | A | 1 |
| | | | | | Mg: 0.05 | | | | | |
| 11 | 0.3 | 0.1 | 0.3 | 0.03 | Mg: 0.02 | remainder | 460 | 88 | A | 1 |
| 12 | 0.3 | 0.1 | 0.3 | 0.03 | Ni: 0.05, Si: 0.1, Ag: 0.05 | remainder | 477 | 82 | A | 1 |
| 13 | 0.3 | 0.1 | 0.3 | 0.03 | Mn: 0.05, Pb: 0.004 | remainder | 470 | 86 | A | 1 |
| 14 | 0.3 | 0.1 | 0.3 | 0.03 | Co: 0.04, Al: 0.02, Cr: 0.03, | remainder | 471 | 81 | A | 1 |
| | | | | | Mg: 0.02, Mn: 0.03, Ca: 0.01, | | | | | |
| | | | | | Ni: 0.03, Ti: 0.02, Zr: 0.03, | | | | | |
| | | | | | Si: 0.03, Ag: 0.01 | | | | | |

TABLE 2

| | | | | | | | Properties | | | |
|---|---|---|---|---|---|---|---|---|---|---|
| | | | | | | | | | | Softening |
| | | | | | | | | | Thermal | Resistance/ |
| | Chemical Component (mass %) | | | | | | Tensile | Electrical | Separation | Hardness |
| Alloy | | | | | Subsidiary | | Strength | Conductivity | Resistance of | Reduction |
| No. | Fe | P | Zn | Sn | Component | Cu | (MPa) | (% IACS) | Solder | Rate (%) |
| 15 | 1.0* | 0.1 | 0.3 | 0.03 | — | remainder | 488 | 79* | A | 1 |
| 16 | 0.004* | 0.1 | 0.3 | 0.03 | — | remainder | 408* | 64* | A | 14* |
| 17 | 0.3 | 0.3* | 0.3 | 0.03 | — | remainder | 497 | 45* | A | 1 |
| 18 | 0.3 | 0.005* | 0.3 | 0.03 | — | remainder | 439* | 86 | A | 11* |
| 19 | 0.3 | 0.1 | 1.5* | 0.03 | — | remainder | 475 | 76* | A | 1 |
| 20 | 0.3 | 0.1 | 0.005* | 0.03 | — | remainder | 463 | 88 | C* | 1 |
| 21 | 0.3 | 0.1 | 0.3 | 0.2* | — | remainder | 471 | 77* | A | 1 |
| 22 | 0.2 | 0.07 | 0.2 | 0.002* | — | remainder | 446* | 88 | A | 5 |
| 23 | 0.3 | 0.1 | 0.3 | 0.03 | Co: 0.1, Al: 0.2, | remainder | 475 | 71* | A | 1 |
| | | | | | Si: 0.1, Mn: 0.1* | | | | | |
| 24 | 2.2* | 0.03 | 0.15 | —* | Cr: 0.1, Ti: 0.1 | remainder | 451 | 65* | A | 3 |

*A portion not satisfying the requirement of the present invention or a portion with inferior properties.

Using the manufactured test material, each of the tests for measuring the tensile strength, the electrical conductivity, the thermal separation resistance of solder, and the softening resistance was performed in the following manner. The measurement results are shown in Table 1.

### (Measurement of Tensile Strength)

From the each test material, three JIS No. 5 specimens were prepared with the longitudinal direction being in parallel to the rolling direction and the tensile strength thereof was measured by performing a tensile test in conformity to the regulation of JIS Z 2241. An average of the tensile strength values of three specimens was defined as the tensile strength of the test material. The test was judged to be passed when the tensile strength was 450 MPa or more.

### (Measurement of Electrical Conductivity)

The electrical conductivity was measured in conformity to the regulation of JIS H 0505. The test was judged to be passed when the electrical conductivity was 80% IACS or more (with respect to each test material, n=1).

### (Measurement of Thermal Separation Resistance of Solder)

In the soldering, a commercially available Sn-3 mass % Ag-0.5 mass % Cu solder was melted and kept at 260° C., and each specimen of 10 mm width×35 mm length, which had been prepared from each test material (n=3) and surface-cleaned, was dipped in the molten solder under the conditions of a dipping speed of 25 mm/sec, a dipping depth of 12 mm, and a dipping time of 5 sec. Solder Checker (Model SAT5100) was used as the soldering apparatus, and active flux was used for the flux. The solder-coated specimen was heated at 175° C. for 72 hr in atmospheric air. The heated specimen was bent at 180° with a bending radius of 0.4 mm by means of a 180° bending jig and bent back −180°. And then, a commercially available pressure-sensitive adhesive tape was attached to the inner side of the bent portion of the specimen, and the tape was peeled off at a stroke. The peeled tape was visually examined, and the test was judged to be passed (A) when out of specimens of n=3, solder separation was not observed in all of three specimens, and judged to be failed (C) when solder separation was observed even in one specimen.

### (Measurement of Softening Resistance)

Three specimens prepared from each test material were measured for the hardness H after heating at 400° C. for 5 minutes and the hardness (H₀) before heating with a micro-Vickers hardness meter by applying a load of 4.9 N, and the hardness reduction rate R was calculated. An average of hardness reduction rates of three specimens was defined as the hardness reduction rate of the test material. The hardness reduction rate R (%) after heating is represented by R={(H₀−H)/H₀}×100. The test was judged to be passed when the hardness reduction rate R was less than 10%.

As shown in Table 1, Alloy Nos. 1 to 14 where the alloy composition satisfies the requirement of the present invention have large tensile strength, high electrical conductivity, excellent thermal separation resistance of solder, and excellent softening resistance and are suitable for use as an LED lead frame.

On the other hand, as shown in Table 2, Alloy Nos. 15 to 22 and 24 where the content of any of Fe, P, Zn and Sn deviates from the requirement of the present invention are poor in any one property or two or more properties of tensile strength, electrical conductivity, thermal separation resistance of solder, and softening resistance. All of Alloy Nos. 15 and 24 where the Fe content is excessive, Alloy No. 17 where the P content is excessive, Alloy No. 19 where the Zn content is excessive, Alloy No. 21 where the Sn content is excessive, and Alloy No. 23 where the total content of subsidiary components (Co, Mn, etc.) is excessive, have a low electrical conductivity. Both of Alloy No. 16 where the Fe content is small and Alloy No. 18 where the P content is small have insufficient tensile strength and poor softening resistance. Alloy No. 20 where the Zn content is small has poor thermal separation resistance of solder. Alloy No. 22 where the Sn content is small has insufficient tensile strength.

### Example 2

Copper alloys (Alloy Nos. 1, 2, 3, 10, 15 and 24) having the compositions shown in Tables 1 and 2 were melted under charcoal covering in atmospheric air in a small-sized electric melting furnace, and ingots having a thickness of 50 mm, a width of 80 mm, and a length of 180 mm were cast. The manufactured ingots were scalped on each of the front/rear surfaces by 5 mm, subjected to a homogenization treatment at 950° C., hot-rolled to sheet materials having a thickness of 12 mm t, and then rapidly cooled. Each of the front/rear surfaces of the sheet materials was scalped by about 1 mm. With respect to these sheet materials, after repeatedly performing cold rolling and precipitation annealing at 500 to 550° C. for 2 to 5 hours, finish cold rolling was performed at a reduction of 40% by using a mirror-finished SiAlON roll with a diameter of 50 mm to manufacture copper alloy strips having a thickness of 0.2 mm and a width of 180 mm, which were used as test materials. In the finish cold rolling, the number of threading passes, the surface roughness of SiAlON roll in each of final and intermediate passes, and the rotational speed of roll were adjusted to obtain copper alloy strips (Test Nos. 1 to 20 in Table 3) having various surface roughnesses. Only with respect to Test No. 7, the sheet surface was mechanically polished after finish cold rolling.

Using the manufactured test materials (copper alloy strips), each of the tests for measuring the surface roughness (Ra, Rz_{JIS}), the thickness of work affected layer, and the number of groove-shaped recesses having a length of 5 μm or more and a depth of 0.25 μm or more observed in the range of a square of 200 μm×200 μm was performed in the following manner. The measurement results are shown in Table 3.

### (Measurement of Surface Roughness)

A specimen of 20 mm in width and 50 mm in length (with the 50 mm length direction being parallel to the rolling direction) was cut out from the central part in the sheet width direction of the manufactured test material, and with respect to the neighborhood of the central part thereof, the surface state of the test material was observed in transverse to a rolling direction by means of AFM (Atomic Force Microscope) to obtain a surface roughness curve (AFM profile). From the AFM profile, Ra (arithmetic average roughness) and Rz_{JIS} (ten-point average roughness) were determined. Measurement was performed at three portions per one specimen, and the maximum value thereof was defined as the surface roughness of the test material.

### (Measurement of Thickness of Work Affected Layer)

A cross-section (length: 20 mm) parallel to the rolling direction and the thickness direction was cut out from the central part in the sheet width of each test material to obtain an observation sample. With respect to each observation sample, the cross-section at arbitrarily selected three portions was observed by SEM (scanning electron microscope) at 40,000 times to obtain a maximum value of the thickness of the work affected layer “composed of fine grains” in each observed portion, and the maximum value of observed values in three visual fields was defined as the thickness of the work affected layer “composed of fine grains” of the test material. Here, when the thickness of the work affected layer is around 0.1 μm or smaller than that, the thickness cannot be exactly measured and is therefore denoted by “-” in the column of Thickness of Work Affected Layer of Table 3.

### (Measurement of Number of Recesses)

The surface of the central part in the sheet width of each test material was observed by SEM at 1,500 times, and the number of groove-shaped recesses having a length of 5 μm or more observed in the range of a square of 200 μm×200 μm (with a pair of its sides running in transverse to a rolling direction) was measured. When a recess having a length of 5 μm or more was observed, after cutting the lengthwise central part of each recess perpendicularly to the length direction, the cross-section thereof was observed by SEM at 40,000 times to measure the maximum depth of the recess, and the number of recesses having a maximum depth of 0.25 μm or more was counted. With respect to each sample, arbitrarily selected three visual fields (each 200 μm×200 μm) were observed, and the number of recesses in the visual field showing the largest number was defined as the number of recesses of the sample. Here, in Test No. 7, a recess could not be clearly distinguished due to polishing mark.

Subsequently, three specimens each having a width of 30 mm and a length of 50 mm (with the 50 mm length direction being parallel to the rolling direction) prepared from the central part in the sheet width of the manufactured test material (copper alloy strip) were subjected to Ag plating under the following conditions, and with respect to the Ag-plated material, the tests for measuring the surface roughness, the crystalline orientation of Ag plating, the grain size of Ag plating, the reflectance, and the brightness after package assembly were performed. The measurement results are shown in Table 3.

### (Ag Plating Conditions)

Each test material was subjected to electrolytic degreasing (5 Adm²×60 sec), acid pickling (20 mass % sulfuric acid×5 sec), Cu flash plating to a thickness of 0.1 to 0.2 μm, and Ag plating to a thickness of 2.5 μm. The composition of the Ag plating solution was as follows: Ag concentration: 80 g/L, free KCN concentration: 120 g/L, potassium carbonate concentration: 15 g/L, additive (trade name: Ag20-10T (produced by Metalor Technologies SA)): 20 ml/L.

### (Measurement of Surface Roughness of Ag-Plated Material)

Using the manufactured Ag-plated material, the surface state of the test material was observed in transverse to a rolling direction by means of AFM (Atomic Force Microscope) to obtain a surface roughness curve (AFM profile), and from the AFM profile, Rz_{JIS} (ten-point average roughness) was determined. The maximum value of measured values obtained by measuring three specimens was defined as Rz_{JIS} of the test material.

### (Measurements of Crystalline Orientation of Ag Plating and Grain Size of Ag Plating)

Using the manufactured Ag-plated material, the crystalline orientation of Ag plating and the grain size of Ag plating were measured on three specimens by EBSD (Electron Backscatter Diffraction) analysis. The EBSD analysis was performed using MSC-2200 manufactured by TSL Solutions under the conditions of a measurement step interval: 0.2 μm and a measurement region of 60×60 μm. The results were such that the measurement results on three specimens could be regarded as identical. Here, in determining the average grain size (equivalent-circle diameter) of Ag plating, a boundary where the misorientation between adjacent measurement points becomes 5° or more is regarded as a grain boundary of Ag plating, and a grain is defined by a region completely surrounded by grain boundaries. The average value of measured values obtained by measuring three specimens was defined as the average grain size of the test material.

### (Measurement of Reflectance of Ag-plated Material)

The total reflectivity (regular reflectance+diffuse reflectance) of the manufactured Ag-plated material was measured using a spectrophotometer, CM-600d, manufactured by Konica Minolta Inc. The test was judged to be passed when the total reflectivity was 92% or more. The average value of total reflectivities obtained by measuring three specimens prepared from each test material was defined as the total reflectivity of the test material.

### (Measurement of Brightness After Package Assembly)

An LED package was assembled using the manufactured Ag-plated material, and the total flux was measured by placing the LED package in a small integral sphere. Specifications of the small integrating sphere were manufacturer: Spectra Corp., model: SLM Series, and size: 10 inches. The test was judged to be passed when the brightness after package assembly was 2.05 lm or more. The average value of measured values obtained by measuring three specimens prepared from each test material was defined as the brightness after assembly of the test material.

TABLE 3

| | | Surface | | | | | | | | |
|---|---|---|---|---|---|---|---|---|---|---|
| | | Roughness of | | | | | | | | |
| | | Copper Alloy | | Thickness of | Number of | Surface | (001) | | | Brightness After |
| | | Strip | | Work | Recesses in | Roughness | Crystallographic | Grain Size of | Reflectance | Package |
| Test | Alloy | Ra | Rz_{JIS} | Affected | 200 μm × 200 μm | Rz_{JIS} After Ag | Orientation of | Ag Plating | After Ag | Assembly (total |
| No. | No. | (μm) | (μm) | Layer (μm) | Range | Plating (μm) | Ag Plating | (μm) | Plating (%) | flux: lm) |
| 1 | 1 | 0.03 | 0.20 | — | 0 | 0.18 | 0.56 | 14.5 | 93.3 | 2.15 |
| 2 | 1 | 0.05 | 0.33 | — | 0 | 0.23 | 0.45 | 13.2 | 92.3 | 2.08 |
| 3 | 1 | 0.05 | 0.36 | — | 2 | 0.26 | 0.45 | 13.1 | 92.1 | 2.07 |
| 4 | 1 | 0.04 | 0.48 | — | 0 | 0.26 | 0.43 | 13.1 | 92.1 | 2.07 |
| 5 | 1 | 0.05 | 0.40 | 0.3 | 1 | 0.26 | 0.43 | 13.1 | 92.1 | 2.07 |
| 6 | 1 | 0.05 | 0.48 | — | 1 | 0.30 | 0.41 | 13.1 | 92.0 | 2.07 |
| 7 | 1 | 0.08* | 0.60* | 1.1* | — | 0.34* | 0.31* | 11.4* | 91.0* | 1.95* |
| 8 | 1 | 0.07* | 0.63* | — | 1 | 0.36* | 0.34* | 11.9* | 91.3* | 1.98* |
| 9 | 1 | 0.09* | 0.65* | — | 3* | 0.40* | 0.27* | 11.1* | 90.7* | 1.93* |
| 10 | 1 | 0.05 | 0.54* | — | 0 | 0.32* | 0.38* | 12.6* | 91.8* | 2.04* |
| 11 | 1 | 0.15* | 0.70* | 0.3 | 10* | 0.45* | 0.20* | 10.0* | 90.0* | 1.97* |
| 12 | 2 | 0.04 | 0.24 | — | 0 | 0.19 | 0.56 | 14.3 | 93.2 | 2.13 |
| 13 | 2 | 0.07* | 0.62* | — | 0 | 0.35* | 0.33* | 11.8* | 91.2* | 1.98* |
| 14 | 3 | 0.03 | 0.23 | — | 0 | 0.19 | 0.54 | 14.4 | 93.3 | 2.14 |
| 15 | 3 | 0.13* | 0.69* | — | 3* | 0.43* | 0.19* | 9.8* | 89.8* | 1.96* |
| 16 | 10 | 0.04 | 0.22 | — | 0 | 0.17 | 0.55 | 14.4 | 93.2 | 2.13 |
| 17 | 10 | 0.09* | 0.65* | — | 0 | 0.40* | 0.26* | 11.0* | 90.6* | 1.92* |
| 18 | 15* | 0.03 | 0.23 | — | 0 | 0.19 | 0.55 | 14.3 | 93.2 | 2.14 |
| 19 | 15* | 0.14* | 0.68* | 0.2 | 0 | 0.44* | 0.20* | 10.0* | 89.9* | 1.98* |
| 20 | 24* | 0.03 | 0.22 | — | 0 | 0.18 | 0.54 | 14.4 | 93.3 | 2.13 |

*A portion not satisfying the requirement of the present invention or a portion with inferior properties.

As shown in Table 3, in all of Test Nos. 1 to 6, 12, 14 and 16 where the alloy composition, the surface roughness (Ra, Rz_{JIS}) of copper alloy sheet, the thickness of work affected layer, and the number of recesses satisfy the requirements of the present invention, the reflectance after Ag plating is 92% or more, and the brightness (total flux) after package assembly is 2.05 lm or more. In all of these, the surface roughness Rz_{JIS} of the Ag-plated material is 0.3 μm or less, the crystalline orientation ((001) crystallographic orientation) of Ag plating is 0.4 or more, and the grain size of Ag plating is 13 μm or more.

On the other hand, in Test Nos. 7 to 11, 13, 15 and 17 where the alloy composition satisfies the requirement of the present invention but any one of the surface roughness (Ra, Rz_{JIS}) of copper alloy sheet, the thickness of work affected layer, and the number of recesses does not satisfy the requirement of the present invention, the reflectance after Ag plating and the brightness (total flux) after package assembly are poor. In all of these, the surface roughness Rz_{JIS} of the Ag-plated material exceeds 0.3 μm, the crystalline orientation ((001) crystallographic orientation) of Ag plating is less than 0.4, and the grain size of Ag plating is less than 13 μm.

In Test Nos. 18 and 20 where the alloy composition does not satisfy the requirement of the present invention but the surface roughness (Ra, Rz_{JIS}) of copper alloy sheet, the thickness of work affected layer, and the number of recesses satisfy the requirements of the present invention, the reflectance after Ag plating is 92% or more, and the brightness (total flux) after package assembly is 2.05 lm or more. In all of these, the surface roughness Rz_{JIS} of the Ag-plated material is 0.3 μm or less, the crystalline orientation ((001) crystallographic orientation) of Ag plating is 0.4 or more, and the grain size of Ag plating is 13 μm or more.

In No. 19 where the alloy composition and the surface roughness (Ra, Rz_{JIS}) of copper alloy sheet do not satisfy the requirements of the present invention, the reflectance after Ag plating and the brightness (total flux) after package assembly are poor. In No. 19, the surface roughness Rz_{JIS} of the Ag-plated material exceeds 0.3 μm, the crystalline orientation ((001) crystallographic orientation) of Ag plating is less than 0.4, and the grain size of Ag plating is less than 13 μm.

While the invention has been described in detail and with reference to specific embodiments thereof, it will be apparent to one skilled in the art that various changes and modifications can be made therein without departing from the spirit and scope of the invention.

This application is based on Japanese Patent Application No. 2014-169481 filed on Aug. 22, 2014, the contents of which are incorporated herein by way of reference.

### INDUSTRIAL APPLICABILITY

The Ag-plated copper alloy sheet or strip of the present invention has a high electrical conductivity and due to its capability of enhancing the reflectance of an Ag plating reflective film, is useful for a lead frame of LED.

1. A copper alloy sheet or strip for a lead frame of LED, comprising Fe: from 0.01 to 0.5 mass %, P: from 0.01 to 0.20 mass %, Zn: from 0.01 to 1.0 mass %, and Sn: from 0.01 to 0.15 mass %, with the remainder consisting of Cu and unavoidable impurities,
wherein a surface roughness thereof is less than 0.06 μm in terms of arithmetic average roughness Ra and is less than 0.5 μm in terms of ten-point average roughness Rz_{JIS}, the number of groove-shaped recesses present on the surface, each having a length of 5 μm or more and a depth of 0.25 μm or more, is 2 or less in a range of a square of 200 μm×200 μm with a pair of its sides running in transverse to a rolling direction, and a thickness of a work affected layer composed of fine grains on the surface is 0.5 μm or less.

2. The copper alloy sheet or strip for a lead frame of LED according to claim 1, further comprising one member or two or more members of Co, Al, Cr, Mg, Mn, Ca, Pb, Ni, Ti, Zr, Si and Ag in a total amount of 0.02 to 0.3 mass %.

3. An Ag-plated copper alloy sheet or strip, wherein Ag plating is applied to a surface of the copper alloy sheet or strip according to claim 1, and a surface roughness of the copper alloy sheet or strip measured in transverse to a rolling direction is 0.3 μm or less in terms of ten-point average roughness Rz_{JIS}.

4. An Ag-plated copper alloy sheet or strip, wherein Ag plating is applied to a surface of the copper alloy sheet or strip according to claim 2, and a surface roughness of the copper alloy sheet or strip measured in transverse to a rolling direction is 0.3 μm or less in terms of ten-point average roughness Rz_{JIS}.
